(19) United States
(12) Patent Application Publication
(10) Pub. No.: US 2007/0026536 A1
(43) Pub. Date: Feb. 1, 2007

(54) Organic thin film transistor for liquid crystal display and method of manufacturing the same

(75) Inventors: Kyu-sik Kim, Yeongtong-gu (KR); Bo-sung Kim, Seoul (KR); Jung-han Shin, Suwon-si (KR); Mun-pyo Hong, Seongnam-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/447,970

(22) Filed: Jun. 7, 2006

(30) Foreign Application Priority Data
Jul. 29, 2005 (KR) 10-2005-0069542

(51) Int. Cl. H01L 21/00

(52) U.S. Cl. 438/1

(57) ABSTRACT

An organic thin film transistor for a liquid crystal display and a method of manufacturing an organic thin film transistor. The method of manufacturing an organic thin film transistor for a liquid crystal display comprises forming a gate conductive film pattern on a substrate; forming a gate insulating film on the substrate and the gate conductive film pattern; forming source and drain electrodes on the gate insulating film; forming an organic semiconductor thin film on an exposed surface of the gate insulating film and the source and drain electrodes; and forming a diamond-like-carbon thin film as an alignment film. A passivation film and the alignment film can both be provided using the diamond-like-carbon thin film.

### CROSS-REFERENCE TO RELATED APPLICATIONS

This application claims priority from Korean Patent Application 10-2005-0069542, filed on Jul. 29, 2005, the entire contents of which are incorporated herein by reference.

### BACKGROUND OF THE INVENTION

1. Field of the Invention

Apparatuses and methods consistent with the present invention relate to an organic thin film transistor for a liquid crystal display, and more particularly, to an organic thin film transistor and a method of manufacturing the organic thin film transistor, which integrates manufacturing a passivation film and a liquid crystal alignment film for the organic transistor in the processes of manufacturing the organic transistor, thereby simplifying the manufacturing process of the liquid crystal display.

2. Description of the Related Art

Recently, various flat panel displays have been developed that can reduce cathode ray tubes with respect to weight and volume, which are the weak points of the cathode ray tube. Such flat panel displays include liquid crystal displays (LCD), field emission displays, plasma display panels (PDP), electro-luminance displays, and the like. Studies are actively undertaken for enhancing the display quality and widening the screens of such flat panel displays.

Of the flat panel displays, the PDPs draw attention due to being light weight and thin, as well as being advantageous for screen widening, due to the simple structure and manufacturing process thereof, but the PDP have drawbacks of low luminous efficiency and luminance, as well as high power consumption. Contrarily, an active matrix LCD, to which a thin film transistor is applied as a switching element, goes through a semiconductor process, and thus is disadvantageous for screen widening. However, the demand for active matrix LCDs is increasing, as it is mainly used as a display unit of a notebook computer. In addition, the LCD has a drawback of consuming a large amount of power due to a backlight unit. Furthermore, the LCD has a drawback of a narrow viewing angle and lots of power loss due to optical elements, such as a polarized light filter, prism sheet, diffusion plate, and the like. In contradistinction, electro luminescent (EL) display elements are largely categorized into inorganic and organic EL elements, according to the material of an emitting layer, and is advantageous, as a self-luminant element that emits light by itself, in that it has a prompt response, high luminous efficiency, and wide viewing angle.

The trend resulting from the above-mentioned various display elements can provide a new market of paper-like flexible displays capable of delivering convenience together with high display quality in a mobile communication domain. In order to implement such a flexible display, elements are required to be highly flexible and durable as well as easily applied to a low-cost manufacturing process in the development of an active drive element array. An organic semiconductor element can be one example of the elements qualifying for such requirements. Organic semiconductor materials currently under study can be polyphenylene, end-substituted thiophen oligomer, pentacene, phthalocyanine, region-regular polymer, and the like.

A patterning process that uses the above-mentioned organic semiconductor materials may be an important aspect in developing flexible displays. After polyacetylene, which is a conjugated organic polymer that shows semiconductor characteristics, has been developed, the organic semiconductor as a new electronic material will be actively under study in various fields, to provide a functional electronic element, optical element, or the like, due to organic characteristics, such as diversity of synthesis methods, easy formation into textile or film, flexibility, conductivity, and low manufacturing cost.

Of the elements using such a conducting polymer or monomer, studies have been done since 1980 regarding organic thin film transistors (OTFT) that use an organic material as an active layer, and are currently ongoing around the world. The organic thin film transistor first developed in 1980's is advantageous in regard to flexibility and convenience in processing and manufacturing, and thus is currently used for matrix displays, such as LCDs. Since the organic transistor, as a new electronic material, is formed with diverse polymer synthesis methods, easily formed into textile or film, flexible, and manufactured at low cost, the application of the organic transistor will widely spread to functional electronic elements, optical elements, and so on, and, compared with a silicon transistor, the OTFT that uses an organic active layer, which is formed of a conducting polymer instead of an amorphous Si, as an organic semiconductor in the transistor, can have a semiconductor layer formed through thermal vapor deposition or an atmospheric pressure printing process, rather than through a chemical vapor deposition (CVD) process using plasma, and can be accomplished through roll-to-roll manufacturing processes using a plastic substrate, if needed, so the OTFT has a significant advantage of enabling transistors to be implemented at a low cost.

FIGS. 1A to 1D are cross-sectional views for showing conventional processes of manufacturing an organic thin film transistor for a liquid crystal display.

First, as shown in FIG. 1A, a gate conductive film pattern 2 is formed on a substrate 1. Next, a gate insulating film 3 is formed over the substrate 1 and the gate conductive film pattern 2.

Next, as shown in FIG. 1B, source/drain electrodes 4 are formed over the gate insulating film 3. Next, an organic semiconductor thin film 5 is formed over the gate insulating film 3 and the source/drain electrodes 4.

Next, in FIG. 1C, a passivation film pattern 6 is formed on the organic semiconductor thin film 5. In order to form the passivation film pattern 6, first, a passivation film is formed and patterned on the organic semiconductor thin film 5, and the passivation film pattern 6 covering a portion of the surface of the organic semiconductor thin film 5 is formed. Lubricant oil, which is an inert liquid that does not damage or degrade the organic semiconductor thin film 5, is mixed with an organic material or a polymer that can be dissolved into the lubricant oil, and this mixture is formed as a thin film on the organic semiconductor thin film 5 through a spin coating, deep coating, or casting method, and thus the passivation film is formed. The lubricant oil can include silicon oil, mineral oil, and paraffin oil.

Next, a monomer of a general polymer can be formed as the organic material mixed with the lubricant oil, and in here, a photoinitiator, which can polymerize the monomer, is added to the mixture of the monomer and the lubricant oil, and thus the passivation film pattern 6 can be formed by directly exposing and patterning the passivation film without using a photoresist film. However, when the photoinitiator is not added, the patterning process can be performed using a photoresist film pattern. For example, isoprene rubber, butane rubber, or butylenes rubber, which can be fully dissolved in the lubricant oil and used as rubber, can be used as the polymer mixed with the lubricant oil.

Next, as shown in FIG. 1D, an etching process is performed on the organic semiconductor thin film 5, using the passivation film pattern 6 as an etching mask, so that an organic semiconductor thin film pattern 7 is formed. The etching process can be performed through a dry etching method using plasma or through a wet etching method using an organic dissolvent. Even though not shown in the drawings, an alignment film is formed on the front surface, and rubbing is performed.

Studies have been continuing on the manufacturing cost reduction and the simplification of the process of manufacturing an organic thin film transistor performed in the above manner.

### SUMMARY OF THE INVENTION

The present invention has been developed to address the above drawbacks and other problems associated with the conventional arrangement. An aspect of the present invention is to provide a method of manufacturing an organic thin film transistor for a liquid crystal display, which integrates the processes of manufacturing a passivation film and a liquid crystal alignment film in the process of manufacturing the organic thin film transistor, thereby simplifying the process of manufacturing the liquid crystal display and reducing manufacturing cost.

An exemplary embodiment of the present invention provides a method of manufacturing an organic thin film transistor for a liquid crystal display, comprising forming a gate conductive film pattern on a substrate; forming a gate insulating film on the substrate and the gate conductive film pattern; forming source and drain electrodes on the gate insulating film; forming an organic semiconductor thin film on an exposed surface of the gate insulating film and the source and drain electrodes; and forming a diamond-like-carbon thin film as an alignment film.

The diamond-like-carbon thin film used as the alignment film may also perform a function of a passivation film of the organic thin film transistor.

A further exemplary embodiment of the present invention provides an organic thin film transistor for a liquid crystal display, comprising a gate conductive film pattern disposed on a substrate; a gate insulating film disposed on the substrate and the gate conductive film pattern; source and drain electrodes disposed on the gate insulating film; an organic semiconductor thin film disposed on a surface of the gate insulating film and the source and drain electrodes; and a diamond-like-carbon thin film that acts as both an alignment film and a passivation film.

The diamond-like-carbon thin film may be an inorganic material. Ion beams may be used for providing directionality on a surface of the diamond-like-carbon thin film. Thus, directionality is given as the ion beams are injected at a predetermined angle with respect to the surface of the diamond-like-carbon thin film.

### BRIEF DESCRIPTION OF THE DRAWINGS

The above aspects of the present invention will be more apparent by describing certain exemplary embodiments of the present invention with reference to the accompanying drawings, in which:

FIGS. 1A to 1D are cross-sectional views for showing a conventional process of manufacturing an organic thin film transistor for a liquid crystal display; and

FIGS. 2A to 2C are cross-sectional views for showing an organic thin film transistor for a liquid crystal display, and a process of manufacturing the organic thin film transistor, according to an exemplary embodiment of the present invention.

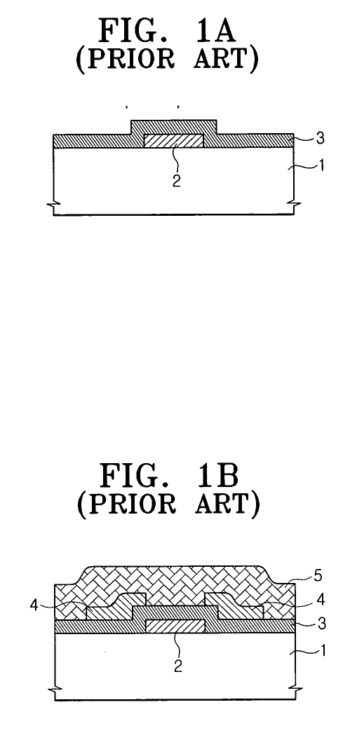

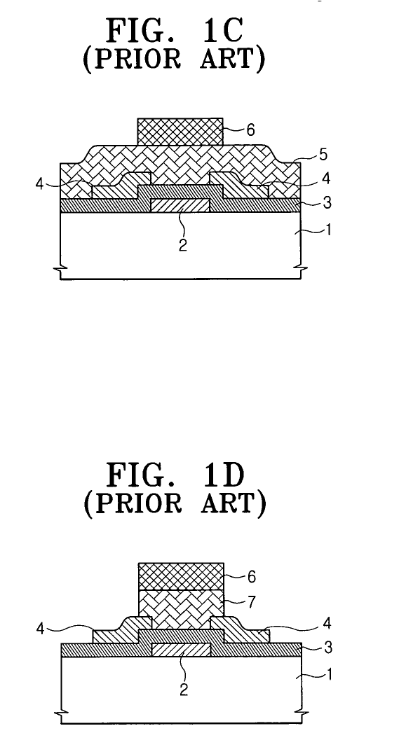

### DESCRIPTION OF THE EXEMPLARY EMBODIMENTS

Hereafter, the present invention will be described in detail with reference to the accompanying drawings.

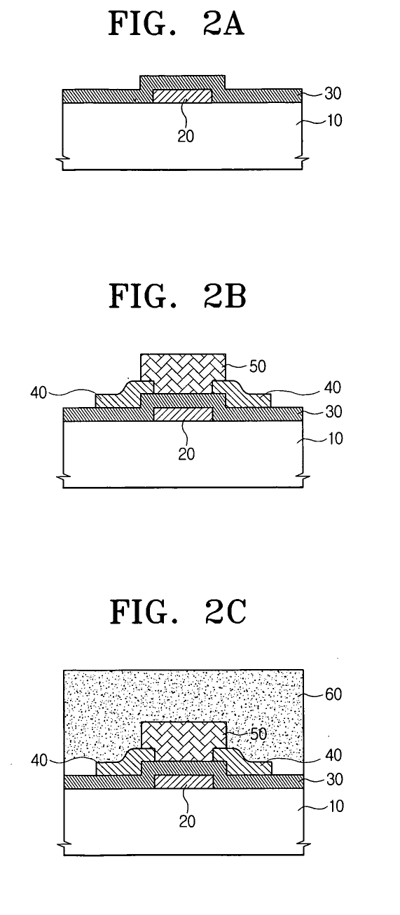

FIGS. 2A to 2C are cross-sectional views for showing an organic thin film transistor for a liquid crystal display, and a process of manufacturing the organic thin film transistor, according to an exemplary embodiment of the present invention.

First, as shown in FIG. 2A, a gate conductive film pattern 20 is formed on a substrate 10. A plastic substrate, silicon substrate, or glass substrate can be used for the substrate 10. The gate conductive film pattern 20 can be formed using a metal film or a conductive polymer film.

That is, the metal film (or the conductive polymer film) is formed on the substrate 10, and a mask film pattern (not shown) exposing a portion of the surface of the metal film (or the conductive polymer film) is formed. Then, the exposed portion of the metal film is removed through an etching process, using the mask film pattern as an etching mask. In such a manner, the gate conductive film pattern 20 is formed, and then the mask film pattern is removed.

Next, a gate insulating film 30 is formed on the substrate 10 and the gate conductive film pattern 20. The gate insulating film 30 is formed of an inorganic thin film material containing a silicon oxide film or a silicon nitride film, or a polymer thin film. Even though not shown in the drawings, after the gate insulating film 30 is formed, a pad for electrically connecting a gate electrode and the gate conductive film pattern 20 is formed.

Next, as shown in FIG. 2B, source and drain electrodes 40 are formed on the gate insulating film 30. A metal film can be used as the source and drain electrodes 40, and especially, a metal having a large work function, such as gold (Au), platinum (Pt), palladium (Pd), Indium Tin Oxide (ITO), or the like, is used. Also, a known conductive polymer film having a large work function in itself can be used to form the source and drain electrodes 40.

In order to form the source and drain electrodes 40, the metal film (or the conductive polymer film) is formed on the gate insulating film 30. Next, a mask film pattern (not shown) exposing a portion of the surface of the metal film (or the conductive polymer film) is formed on the metal film (or the conductive polymer film).

Next, if the exposed portion of the metal film (or the conductive polymer film) is removed through an etching process using the mask film pattern as an etching mask, the source and drain electrodes 40 are produced to expose a portion of the gate insulating film 30. In such a manner, after the source and drain electrodes 40 are formed, the mask film pattern is removed. Alternatively, for the above-mentioned metals on which such an etching process is difficult to be performed, a lift-off method can be used, wherein a photoresist pattern exposing the portion on which the source and drain electrodes are deposited is formed on the gate insulating film 30, the metals are deposited on the photoresist pattern, and the photoresist film is dissolved and removed together with the metal film formed thereon.

Next, an organic semiconductor thin film 50 is patterned and formed on the exposed surface of the gate insulating film 30 and the source and drain electrodes 40. On the other hand, although not shown in the drawings, the metal film or the photoresist can be formed on the organic semiconductor thin film 50 for patterning the organic semiconductor thin film 50.

A low molecular organic semiconductor thin film, or, occasionally in an application field where a high speed operating frequency is not required, a polymer organic semiconductor thin film can be used as the organic semiconductor thin film 50. When a low molecular organic semiconductor thin film, such as pentacene or the like, is used, the organic semiconductor thin film is formed through a thermal evaporation method or a vacuum evaporation method. When a polymer organic semiconductor thin film is used as the organic semiconductor thin film 50, P3HT (3-hexylthiophene), F8T2 (fluorine-bithiophene copolymer), or the like is used.

Next, as shown in FIG. 2C, a diamond-like-carbon thin film (hereafter, referred to as a DLC thin film) 60 is formed as an alignment film. The DLC thin film 60 used as an alignment film in this embodiment is an inorganic material that simultaneously implements both functions of a passivation film and a liquid crystal alignment film which are used when a conventional organic thin film transistor is manufactured.

The DLC thin film is used as an alignment film since the DLC thin film has a double bond structure between carbon atoms. Specifically, the carbon atoms of the DLC thin film have double bond structures between each other.

When the carbon double bond structure is broken by external force and is changed into a single bond structure, the single bonded carbon atoms are in a radical state chemically and electrically having a polarity.

If liquid crystal used for a liquid crystal display is applied on the DLC thin film 60 having a radical state as above, the liquid crystal is self-aligned by the DLC thin film 60 of a radical state, since liquid crystal molecules have the characteristics of crystal and liquid, and have a direction factor orientating the molecules with the direction of an electric field like a compass.

As described above, the invention simultaneously implements the functions of the passivation film and the liquid crystal alignment film, using the diamond-like-carbon thin film. Accordingly, since the processes of manufacturing a passivation film and a liquid crystal alignment film are integrated into one process, the present invention has an advantage of reducing a manufacturing cost, due to the simplified manufacturing process when organic thin film transistors are manufactured.

The foregoing embodiments and aspects are merely exemplary and are not to be construed as limiting the present invention. The present teachings can be readily applied to other types of apparatuses. Also, the description of the exemplary embodiments of the present invention is intended to be illustrative, and not to limit the scope of the claims, and many alternatives, modifications, and variations will be apparent to those skilled in the art.

What is claimed is:

1. A method of manufacturing an organic thin film transistor for a liquid crystal display, comprising:
forming a gate conductive film pattern on a substrate;
forming a gate insulating film on the substrate and on the gate conductive film pattern;
forming a source electrode and a drain electrode on the gate insulating film;
forming an organic semiconductor thin film on an exposed surface of the gate insulating film and on the source electrode and on the drain electrode; and
forming a diamond-like-carbon thin film on the organic semiconductor thin film as an alignment film.

2. The method as claimed in claim 1, wherein the diamond-like-carbon thin film is provided to function as a passivation film of the organic thin film transistor.

3. The method as claimed in claim 1, wherein the diamond-like-carbon thin film is an inorganic material.

4. The method as claimed in claim 1, wherein ion beams are injected at a predetermined angle with respect to a surface of the diamond-like-carbon thin film to provide directionality.

5. The method as claimed in claim 1, wherein the diamond-like-carbon thin film is formed on the organic semiconductor thin film, on the source electrode, on the drain electrode and on the substrate.

6. An organic thin film transistor for a liquid crystal display, the organic thin film transistor comprising:
a gate conductive film disposed on a substrate;
a gate insulating film disposed on the substrate and on the gate conductive film pattern;
a source electrode and a drain electrode on the gate insulating film;
an organic semiconductor thin film disposed on a surface of the gate insulating film between the source electrode and the drain electrode; and
a diamond-like-carbon thin film disposed on the organic semiconductor to act as both an alignment film and a passivation film.

7. The organic thin film transistor as claimed in claim 6, wherein the diamond-like-carbon thin film is an inorganic material.

8. The organic thin film transistor as claimed in claim 6, wherein ion beams are provided for directionality on a surface of the diamond-like-carbon thin film.

9. The organic thin film transistor as claimed in claim 6, wherein the diamond-like-carbon thin film is formed on the organic semiconductor thin film, on the source electrode, on the drain electrode and on the substrate.
